(19) United States
(12) Patent Application Publication
(10) Pub. No.: US 2005/0000426 A1
(43) Pub. Date: Jan. 6, 2005

(54) Methods and apparatus for depositing a thin film on a substrate

(76) Inventors: Ki-Vin Im, Gyeonggi-do (KR); In-Sung Park, Seoul (KR); Sung-Tae Kim, Seoul (KR); Young-Sun Kim, Gyeonggi-do (KR); Jae-Hyun Yeo, Seoul (KR); Yun-Jung Lee, Seoul (KR); Ki-Yeon Park, Gyeonggi-do (KR)

Correspondence Address: MYERS BIGEL SIBLEY & SAJOVEC, PO BOX 37428, RALEIGH, NC, 27627, US

(21) Appl. No.: 10/747,803

(22) Filed: Dec. 29, 2003

(30) Foreign Application Priority Data
Dec. 30, 2002 (KR) 2002-86874

(51) Int. Cl. C23C 16/00

(52) U.S. Cl. 118/715; 427/255.28

(57) ABSTRACT

An apparatus for depositing a thin film includes a reaction chamber, a reaction gas provider to supply a reaction gas and/or inert gas to the reaction chamber, an oxidant provider to supply a first oxidant and a second oxidant to the reaction chamber, and an air drain to exhaust gas from the apparatus. The oxidant provider is operable to supply the second oxidant to the reaction chamber using the first oxidant as a transfer gas.

### RELATED APPLICATIONS

The present application claims priority from Korean Patent Application No. 2002-86874, filed Dec. 30, 2002, the disclosure of which is incorporated by reference herein in its entirety.

### FIELD OF THE INVENTION

The present invention generally relates to an apparatus for manufacturing semiconductor devices and, more particularly, to an apparatus for depositing a metal oxide layer on a substrate.

### BACKGROUND OF THE INVENTION

Generally, Atomic Layer Deposition (ALD) is a method used for forming thin metal oxide layers, for example, an aluminum oxide layer, a hafnium oxide layer or the like. In ALD, a thin film is formed by serially providing reaction gases in a chamber. The thin film is formed on a surface of a substrate by reaction at the surface of the substrate, such that the film is formed to a uniform thickness. In addition, because the thin film develops proportionally to the amount of the reaction material, the thickness of the layer can be precisely controlled.

According to some methods, a metal oxide layer is formed by cyclically repeating ALD several times. Precursor and oxidant are serially introduced into the chamber in order to form the metal oxide layer having a desired thickness. The oxidant may include water vapor, hydrogen peroxide, ozone, etc., containing oxygen atoms. Ozone has high reactivity and reacts with precursor coated on the substrate to form a thin, stable layer having good step coverage. Using ozone as the oxidant, however, has the disadvantage of a low deposition rate. If water vapor or hydrogen peroxide having high polarity are used as the oxidant, non-reacted water molecules or hydroxides may not be entirely removed. The residual water molecules or hydroxides may react with precursor provided in a subsequent cycle to form a new thin layer. In this case, the deposition rate of the thin film is high but the step coverage may be poor.

Recently, a method using both ozone and water vapor has been developed in order to satisfy the need for both high deposition rate and good step coverage.

FIG. 1 is a schematic piping diagram showing a prior art apparatus for depositing a thin film that provides ozone together with water vapor.

Referring to FIG. 1, the prior art apparatus for depositing a thin film includes an ozone provider 2, a reaction gas provider 4, a reaction chamber 10, a selection transfer 3, and a drainage pump 20. The ozone provider 2 includes an ozone generator 30, an ozone supply line 53 and a first process valve 1. The ozone generator 30 generates ozone that is provided to the reaction chamber 10. The ozone supply line 53 serves as a transfer path between the ozone generator 30 and the reaction chamber 10. The first process valve 1 is installed in the ozone supply line 53 and permits or interrupts the flow of ozone.

The reaction gas provider 4 includes an oxidant container 50a, a reaction material container 50b, an inert gas generator 40 and supply lines. The oxidant container 50a stores H₂O or H₂O₂ as a liquid oxidant source. The H₂O or H₂O₂ is present in the container 50a in both liquid phase and vapor phase. The reaction material container 50b stores precursor. The inert gas generator 40 generates inert gas that transports oxidant and reaction material to the reaction chamber 10. The supply lines serve as supply paths for the inert gas, oxidant and reaction gas.

The reaction gas provider 4 further includes a first supply line 12, a second supply line 22 and a first drainage line 42. The first supply line 12 connects the inert gas provider 40 directly to the reaction chamber 10. The second supply line 22 connects the inert gas generator 40 to the reaction chamber 10 through the oxidant container 50a. The first drainage line 42 diverges from the second supply line 22 and connects the inert gas provider 40 directly to the drainage pump 20.

The reaction gas provider 4 also includes a third supply line 32 and a second drainage line 52. The third supply line 32 connects the inert gas generator 40 to the reaction chamber 10 through the reaction material container 50b. The second drainage line 52 diverges from the third supply line 32 and connects the inert gas generator 40 directly to the drainage pump 20.

First and second drainage valves 41 and 51 are installed in the first and second drainage lines 42 and 52, respectively. The first and second drainage valves 41 and 51 interrupt or permit the flow of inert gas.

A first selection valve 21 and a second process valve 9 are installed in the second supply line 22. The first selection valve 21 interrupts or permits the flow of inert gas to the oxidant container 50a. The second process valve 9 interrupts or permits the flow of oxidant to the reaction chamber 10.

A second selection valve 31 and a third process valve 19 are installed in the third supply line 32. The second selection valve 31 interrupts or permits the flow of inert gas to the reaction material container 50b. The third process valve 19 interrupts or permits the flow of reaction gas to the reaction chamber 10.

The selection transfer 3 includes supply valves 5, 15, 25 and 35, and bypass valves 7, 17, 27 and 37. The supply valves 5, 15, 25 and 35 interrupt or permit the flow of oxidant and reaction gas to the reaction chamber 10. The bypass valves 7, 17, 27 and 37 operate inversely to the supply valves 5, 15, 25 and 35 to exhaust the oxidant and the reaction gas to the drainage pump 20.

As illustrated above, the prior art apparatus for depositing a thin film provides each of a first oxidant gas and a second oxidant vapor from a liquid source through independent supply lines to the reaction chamber. A plurality of process valves and supply valves are required to control the amounts of each of the oxidants. Accordingly, the breakdown frequency of one or more of the valves may be high and the valves may be complicated to control, thereby causing apparatus malfunction.

### SUMMARY OF THE INVENTION

According to embodiments of the present invention, an apparatus for depositing a thin film includes a reaction chamber, a reaction gas provider to supply a reaction gas and/or inert gas to the reaction chamber, an oxidant provider to supply a first oxidant and a second oxidant to the reaction chamber, and an air drain to exhaust gas from the apparatus. The oxidant provider is operable to supply the second oxidant to the reaction chamber using the first oxidant as a transfer gas.

According to further embodiments of the present invention, an apparatus for depositing a thin film includes a reaction chamber, a reaction gas provider to supply a reaction gas and an inert gas to the reaction chamber, an oxidant provider to supply a first oxidant and a second oxidant to the reaction chamber, and an air drain to exhaust gas from the apparatus. The oxidant provider includes an oxidant generator to generate the first oxidant, an oxidant container to store the second oxidant, a first supply line to supply the first oxidant directly to the reaction chamber from the oxidant generator, and a second supply line fluidly connecting the oxidant generator to the reaction chamber via the oxidant container to supply the second oxidant to the reaction chamber using the first oxidant as a transfer gas.

According to further embodiments of the present invention, an apparatus for depositing a thin film includes: a reaction chamber; an oxidant generator to generate a first oxidant; an oxidant container; a second oxidant stored in the oxidant container; a reaction material container; a reaction gas stored in the reaction material container; an inert gas generator to generate an inert gas; a drainage pump to exhaust gas from the apparatus; a first supply line to supply the first oxidant directly to the reaction chamber from the oxidant generator; a second supply line connecting the oxidant generator to the reaction chamber via the oxidant container to provide the second oxidant to the reaction chamber using the first oxidant as a transfer gas; a third supply line to supply the inert gas directly to the reaction chamber from the inert gas generator; a fourth supply line connecting the inert gas generator to the reaction chamber via the reaction material container to supply the reaction gas to the reaction chamber using the inert gas as a transfer gas; and a drainage line diverging from the fourth supply line to exhaust the inert gas directly to the drainage pump.

According to further embodiments of the present invention, an apparatus for depositing a thin film includes: a reaction chamber; an oxidant generator to generate a first oxidant; an oxidant container to generate a second oxidant; a second oxidant stored in the oxidant container; a reaction material container; a reaction gas stored in the reaction material container; an inert gas generator to generate an inert gas; a drainage pump to exhaust gas from the apparatus; a first supply line to supply the first oxidant directly to the reaction chamber from the oxidant generator; a second supply line connecting the oxidant generator to the reaction chamber via the oxidant container to provide the second oxidant to the reaction chamber using the first oxidant as a transfer gas; a third supply line to supply the inert gas directly to the reaction chamber from the inert gas generator; and a fourth supply line diverging from the third supply line and connecting the inert gas generator to the reaction chamber via the reaction material container to supply the reaction gas to the reaction chamber using the inert gas as a transfer gas.

According to method embodiments of the present invention, a method for depositing a thin film includes supplying a reaction a gas to a reaction chamber. A mixture of a first oxidant and a second oxidant is supplied to the reaction chamber. The first oxidant is used as a transfer gas for the second oxidant gas.

Objects of the present invention will be appreciated by those of ordinary skill in the art from a reading of the figures and the detailed description of the preferred embodiments which follow, such description being merely illustrative of the present invention.

### BRIEF DESCRIPTION OF THE DRAWINGS

FIG. 1 is a schematic piping diagram showing a prior art apparatus for depositing a thin film;

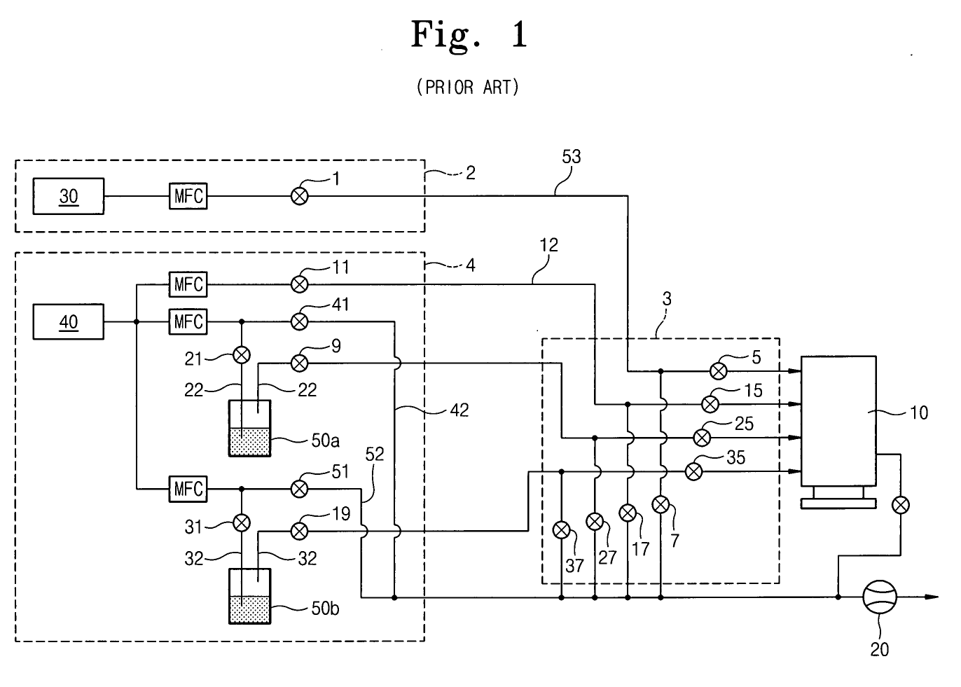

FIG. 2 is a schematic piping diagram showing an apparatus for depositing a thin film according to embodiments of the present invention;

FIG. 3 is a schematic view of an oxidant container in accordance with embodiments of the present invention; and

FIG. 4 is a schematic piping diagram showing an apparatus for depositing a thin film according to further embodiments of the present invention.

### DETAILED DESCRIPTION OF THE PREFERRED EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the relative sizes of regions may be exaggerated for clarity. It will be understood that when an element such as a layer, region or substrate is referred to as being “on” or “connected to” another element, it can be directly on the other element or intervening elements may also be present. In contrast, when an element is referred to as being “directly on” another element, there are no intervening elements present except that, in the case of connecting piping or lines, there may be one or more valves, mass flow controllers or other flow control devices installed in the line between the referenced components.

Where valves are described herein as operating inversely, it is meant that when one valve is open the other valve is closed and vice-versa. According to some preferred embodiments, the valves are operated inversely automatically (i.e., when the first valve is transitioned from closed to open, the other valve is automatically transitioned from open to closed, and vice-versa).

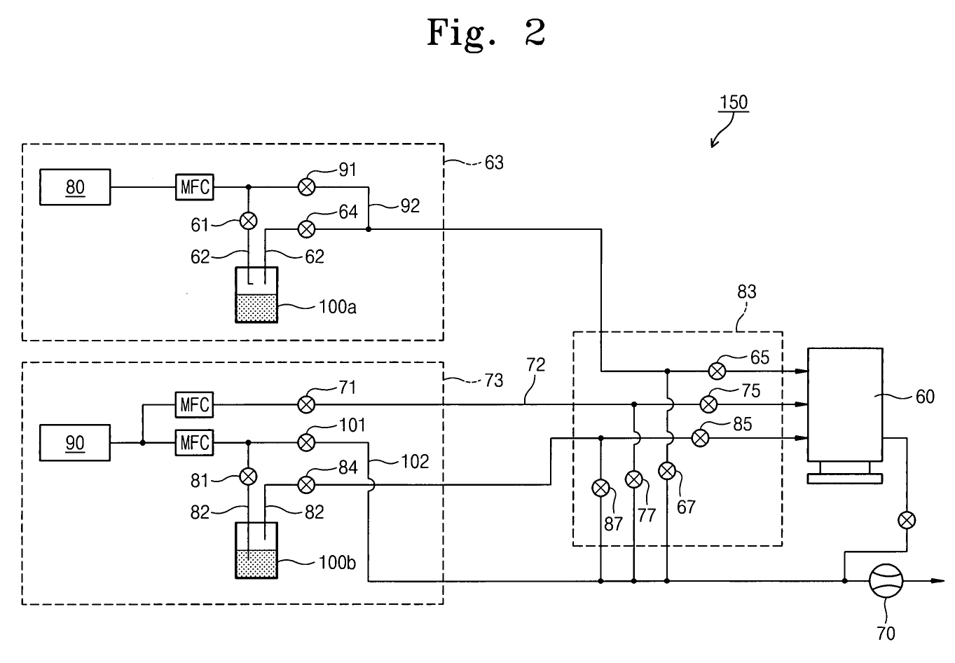

FIG. 2 is a schematic pipe diagram showing an apparatus 150 according to embodiments of the present invention for depositing a thin film is shown therein. The apparatus 150 includes a reaction chamber 60, an oxidant provider 63, a reaction gas provider 73, a selection transfer 83 and an air drain 93.

The oxidant provider 63 includes an oxidant generator 80 and an oxidant container 100a. The oxidant generator 80 generates a first oxidant and the oxidant container 100a holds a second oxidant. The oxidant container 100a provides an environment in which the second oxidant has a predetermined vapor pressure. According to some embodiments, the second oxidant is provided as a liquid source such that the second oxidant is present in the oxidant container 100a in liquid phase.

A first supply line 92 connects the oxidant generator 80 directly to the reaction chamber 60. A second supply line 62 connects the oxidant generator 80 to the reaction chamber 60 via the oxidant container 100a.

A first process valve 91 is installed in the first supply line 92. The first process valve 91 controls the flow of the first oxidant to the reaction chamber 60 from the oxidant generator 80.

A first selection valve 61 and a second process valve 64 are installed in the second supply line 62. The first selection valve 61 controls the flow of the first oxidant from the oxidant generator 80 to the oxidant container 100a. The second process valve 64 controls the flow of the second oxidant and the first oxidant from the oxidant container 100a to the reaction chamber 60 through the second supply line 62.

The first selection valve 61 and the second process valve 64 operate inversely to the first process valve 91 to control the oxidant flow. When the first process valve 91 is opened and the first selection valve 61 and the second process valve 64 are closed, the oxidant from the oxidant generator 80 is provided directly to the reaction chamber 60. When the first process valve 91 is closed and the first selection valve 61 and the second process valve 64 are opened, the first oxidant from the oxidant generator 80 flows into the oxidant container 100a and carries or transfers the second oxidant from the oxidant container 100a to the reaction chamber 60. A mass flow controller (MFC) is installed between the oxidant generator 80 and the first process valve 91 and the first selection valve 61 in order to control the amount of the first oxidant supplied.

The oxidant provider 63 may supply one or more oxidant gases to the reaction chamber 60, and one or more of these oxidant gases may be provided from gaseous and liquid sources. According to some embodiments, a plurality of oxidant generators and oxidant containers may be combined in a single apparatus to supply multiple oxidant gases from multiple gaseous and/or liquid oxidant sources. According to some embodiments, the first oxidant is a gas such as ozone or nitride monoxide. According to some embodiments, the second oxidant is provided as a liquid source such as liquid water or hydrogen peroxide.

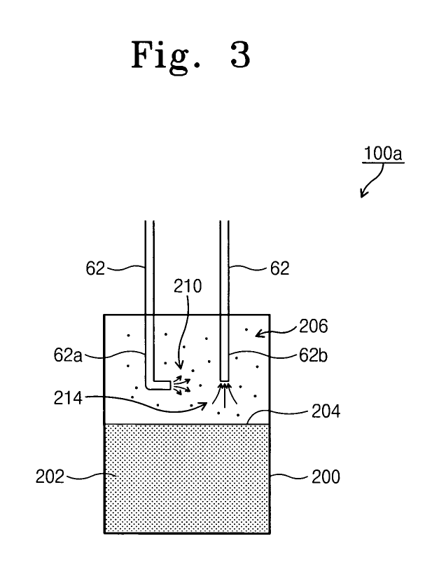

FIG. 3 is an enlarged, schematic view showing a suitable oxidant container 100a in accordance with embodiments of the present invention. The arrangement and apparatus shown in FIG. 3 and described below may be used in other deposition apparatus, such as the apparatus 350 discussed hereinafter. Alternatively, this oxidant container 100a may be replaced in the apparatus 150 with other suitable oxidant container apparatus.

Referring to FIG. 3, the oxidant container 100a includes a canister 200, a pressurization line 62a and a gas supply line 62b. The canister 200 stores the second oxidant.

The second oxidant is provided as a liquid source 202. According to some embodiments, the second oxidant is a liquid in its normal or natural state (i.e., at standard temperature and pressure). The liquid source 202 is provided in the canister 200 up to an upper surface 204. A headspace 206 is defined in the container 200 above the upper surface 204. The pressure and temperature of the second oxidant in the canister 200 are maintained such that a selected amount of the liquid source 202 vaporizes to provide second oxidant in the vapor phase in the headspace 206.

The pressurization line 62a is inserted in the canister 200 with its open end positioned in the headspace 206 over the upper surface 204 of the liquid source 202 in the canister 200. The pressurization line 62a is connected to the oxidant generator 80 and ejects the first oxidant 210 from its open end and into the canister 200. The gas supply line 62b is also inserted in the canister 200 with its open end positioned in the headspace 206 over the upper surface 204 of the liquid source 202. The gas supply line 62b is connected to the process chamber 60.

The second oxidant liquid source 202 is contained at a predetermined level and the pressure and temperature of the second oxidant in the canister are controlled to suitably manage the vapor pressure of the second oxidant. Ozone dissolves rapidly when it comes in contact with water. Therefore, as illustrated above, the openings of the pressurization line 62a and the gas supply line 62b may be positioned over the second oxidant liquid source 202 such that they are spaced apart from the upper surface 204 of the liquid source 202 a predetermined distance. The first oxidant 210 flows into the canister 200 through the pressurization line 62a, mixes with the second oxidant vapor in the headspace 206, and is exhausted from the canister 200 through the gas supply line 62b together as a mixture 214 with the second oxidant vapor.

Referring back to FIG. 2, the reaction gas provider 73 includes an inert gas generator 90, a reaction material container 100b, a third supply line 72, a fourth supply line 82, and a drainage line 102. The inert gas generator 90 generates the inert gas that is provided to the reaction chamber 60. The reaction container 100b holds reaction material which may be in the form of a liquid source. The third supply line 72 connects the inert gas generator 90 directly to the reaction chamber 60. The fourth supply line 82 connects the inert gas generator 90 to the reaction chamber 60 via the reaction material container 100b. The drainage line 102 diverges from the fourth supply line 82 and exhausts the inert gas directly to a drainage pump 70.

A third process valve 71 is installed in the third supply line 72. The third process valve 71 interrupts or permits flow of the inert gas from the inert gas generator 90 to the reaction chamber 60.

A second selection valve 81 and a fourth process valve 84 are installed in the fourth supply line 82. The second selection valve 81 interrupts or permits flow of the inert gas from the inert gas generator 90 to the reaction material container 100b. The fourth process valve 84 interrupts or permits flow of the inert gas from the reaction material container 100b to the reaction chamber 60. In addition, a drainage valve 101 is installed in the drainage line 102 and operates inversely to the second selection valve 81 to exhaust the inert gas to the drainage pump 70 through the drainage line 102.

When the drainage valve 101 is closed and the second selection valve 81 and the fourth process valve 84 are opened, the inert gas from the inert gas generator 90 transfers the reaction material of the reaction material container 100b to the reaction chamber 60. When the second selection valve 81 and the fourth process valve 84 are closed, the drainage valve 101 is opened and the inert gas generated from the inert gas generator 90 is exhausted directly through the drainage line 102 to the drainage pump 70.

The selection transfer 83 includes supply valves 65, 75 and 85 which interrupt or permit flow of the first oxidant, the second oxidant, the inert gas and the reaction gas. The first supply valve 65 controls flow of the first oxidant and the second oxidant (mixed with the first oxidant) into the reaction chamber 60. The second supply valve 75 controls the flow of the inert gas into the reaction chamber 60. The third supply valve 85 controls the flow of reaction gas into the reaction chamber 60.

The selection transfer 83 further includes first, second and third bypass valves 67, 77 and 87 that exhaust the first oxidant, the second oxidant, the inert gas and the reaction gas through the drainage pump 70 by operating in inverse relation to each of the supply valves 65, 75, and 85, respectively. The bypass valves 67, 77, and 87 each play a role in preventing rapid changes in the pressure of the supply line.

According to methods of the present invention, the third supply valve 85 is opened and the reaction gas is provided to the reaction chamber 60 from the reaction material container 100b. A reaction gas layer, i.e., a precursor layer, is formed on a substrate disposed in the reaction chamber 60. Thereafter, the third supply valve 85 is closed and at the same time, the third bypass valve 87 is opened to exhaust the reaction gas to the drainage pump 70. Then, the second supply valve 75 is opened and the inert gas flows into the reaction chamber 60 to purge the inside of the reaction chamber 60.

Next, the first supply valve 65 is opened so that the first and second oxidants flow together (e.g., as the mixture 214) into the reaction chamber 60 to form a metallic oxide layer such as an aluminum oxide layer or a hafnium oxide layer on the substrate. The first supply valve 65 is then closed and at the same time the first bypass valve 67 is opened. Then, the second supply valve 75 is opened to purge the inside of the reaction chamber 60.

The foregoing cycles are repeated several times to form a thin layer on the substrate. The first selection valve 61 and the first process valve 91 are suitably controlled to simultaneously provide the first and second oxidants as a mixture to the reaction chamber 60 or to provide only the first oxidant to the reaction chamber 60.

In accordance with some embodiments of the present invention, the mixture 214 of the first and second oxidants is provided to the reaction chamber 60 via the line 62, and thereafter the first oxidant is provided to the reaction chamber 60 alone (i.e., without the second oxidant) via the line 92 only. In accordance with some methods of the present invention, water vapor and ozone are simultaneously provided to the reaction chamber in an initial step of the depositing process, and then only ozone is provided to the reaction chamber to achieve good step coverage. Such methods may be employed to achieve rapid deposition.

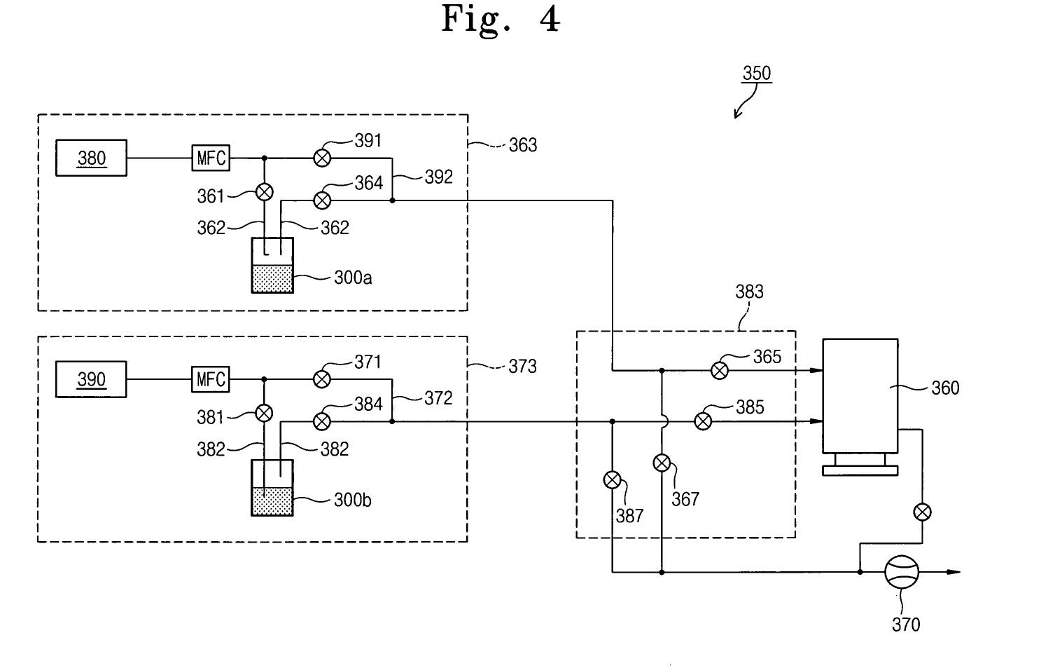

FIG. 4 is a schematic pipe diagram showing an apparatus for depositing a thin film according to further embodiments of the present invention.

Referring to FIG. 4, the apparatus includes a reaction chamber 360, an oxidant provider 363, a reaction gas provider 373, a selection transfer 383, and an air drain.

The oxidant provider 363 includes an oxidant generator 380 and an oxidant container 300a. The oxidant generator 380 generates a first oxidant that is provided to the reaction chamber 360. The oxidant container 300a contains a second oxidant. The oxidant container 300a provides an environment in which the second oxidant has a predetermined vapor pressure. According to some embodiments, the second oxidant is provided as a liquid source such that the second oxidant is present in the oxidant container 300a in liquid phase. According to some embodiments, the oxidant container 300a corresponds to the oxidant container 100a described above with reference to FIG. 3.

A first supply line 392 connects the oxidant generator 380 directly to the reaction chamber 360. A second supply line 362 connects the oxidant generator 380 to the reaction chamber 360 via the oxidant container 100a.

A first process valve 391 and second process valve 364 are installed in the first supply line 392. The first process valve 391 interrupts or permits flow of the first oxidant from the oxidant generator 380 to the reaction chamber 360. The second process valve 364 interrupts or permits flow of the second oxidant and the first oxidant from the oxidant container 300a to the reaction chamber 360. The first selection valve 361 and the second process valve 364 operate inversely to the first process valve 391.

According to some embodiments, the first oxidant may be a gas such as ozone or nitride monoxide. According to some embodiments, the second oxidant is provided as a liquid source such as liquid water or hydrogen peroxide.

The second oxidant is transferred to the reaction chamber 360 by the first oxidant that flows into the oxidant container 300a. The oxidant provider 363 may provide one or more oxidant gases to the reaction chamber 360, and one or more of these oxidant gases may be provided from gaseous and liquid sources. According to some embodiments, a plurality of oxidant generation devices and a plurality of oxidant containers may be provided and suitably combined to supply multiple oxidant gases from multiple gaseous and/or liquid oxidant sources.

The reaction gas provider 373 includes an inert gas generator 390, a reaction material container 300b, a third supply line 372 and a fourth supply line 382. The inert gas generator 390 generates inert gas that is provided to the reaction chamber 360. The reaction container 300b contains reaction material. The third supply line 372 connects the inert gas generator 390 directly to the reaction chamber 360. The fourth supply line 382 is diverged from the third supply line and connected to the reaction chamber 360 via the reaction material container 300b.

A third process valve 371 is installed in the third supply line 372. The third process valve 371 interrupts or permits the flow of inert gas that flows to the reaction chamber 360 from the inert gas generator 390. A second selection valve 381 and a fourth process valve 384 are installed in the fourth supply line 382. The second selection valve 381 interrupts or permits the flow of the inert gas from the inert gas generator 390 to the reaction container 300b. The fourth process valve 384 interrupts or permits the flow of reaction gas from the reaction container 300b to the reaction chamber 360.

The selection transfer 383 includes supply valves 365 and 385 that interrupt or permit flow of the first and second oxidants, the inert gas and the reaction gas into the reaction chamber 360. The first supply valve 365 interrupts or permits the flow of the first oxidant and second oxidant (mixed with the first oxidant) into the reaction chamber 360. The second supply valve 385 interrupts or permits the flow of the inert gas and the reaction gas into the reaction chamber 360.

The selection transfer 383 further includes first and second bypass valves 367 and 387 that exhaust the first and second oxidants, the inert gas and the reaction gas by operating inversely to each of the supply valves 365 and 385. The bypass valves 367 and 387 may prevent drastic variations in the pressure in the supply lines.

According to methods of the present invention, the second selection valve 381 and the fourth process valve 384 are opened and the third process valve 371 is closed to provide reaction gas to the reaction chamber 360 from the reaction material container 300b. The second supply valve 385 is opened so that the reaction gas flows into the reaction chamber 360 to form a reaction gas layer (i.e., a precursor layer) on the substrate disposed in the reaction chamber 360. Thereafter, the second supply valve 385 may be closed and the second bypass valve 387 immediately opened to exhaust the reaction gas directly to the drainage pump 370.

The inert gas may be flowed into the reaction chamber 360 to purge the inside of the chamber 360 by closing the second selection valve 381 and the fourth process valve 384, opening the third process valve 371, and opening the second supply valve 385. The second supply valve 385 is closed and the second bypass valve 387 is opened at the same time so that the inert gas is exhausted directly to the drainage pump 370.

Thereafter, the first supply valve 365 is opened so that the first and second oxidants flow together (e.g., as a mixture) into the reaction chamber 360 and react with the precursor layer on the substrate to form a metal oxide layer such as an aluminum oxide layer or a hafnium oxide layer. As soon as the supply valve 365 is closed, the first bypass valve 367 is opened and the second supply valve 375 [?] is opened to purge the inside of the reaction chamber 360.

The cycle explained above may be repeated several times to form a thin layer on the substrate. The first selection valve 361 and the first process valve 391 are suitably controlled to provide first and second oxidants to the reaction chamber 360 or to provide only the first oxidant to the reaction chamber 360.

Apparatus in accordance with the present invention may be used to transfer an oxidant from a liquid source to a process chamber using an oxidant gas as a transfer gas, thereby allowing for a reduction in the number of valves installed in an oxidant supply line or lines. The oxidant gas used as the transfer gas may be provided to the process chamber with the second oxidant through a supply line, and the oxidant gas and the oxidant from the liquid source may be provided together to the process chamber through the same line. As a result, the risk of valve malfunction in the supply line may be decreased, such that the process can be stably performed.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the invention.

1. An apparatus for depositing a thin film, the apparatus comprising:
a) a reaction chamber;
b) a reaction gas provider to supply a reaction gas and/or inert gas to the reaction chamber;
c) an oxidant provider to supply a first oxidant and a second oxidant to the reaction chamber; and
d) an air drain to exhaust gas from the apparatus;
e) wherein the oxidant provider is operable to supply the second oxidant to the reaction chamber using the first oxidant as a transfer gas.

2. The apparatus of claim 1 wherein the oxidant provider is further operable to supply the first oxidant to the reaction chamber without the second oxidant.

3. The apparatus of claim 1 wherein the oxidant provider is operative to supply the second oxidant to the reaction chamber from a liquid source of the second oxidant.

4. An apparatus for depositing a thin film, the apparatus comprising:
a) a reaction chamber;
b) a reaction gas provider to supply a reaction gas and an inert gas to the reaction chamber;
c) an oxidant provider to supply a first oxidant and a second oxidant to the reaction chamber; and
d) an air drain to exhaust gas from the apparatus;
e) wherein the oxidant provider includes:
an oxidant generator to generate the first oxidant;
an oxidant container to store the second oxidant;
a first supply line to supply the first oxidant directly to the reaction chamber from the oxidant generator; and
a second supply line fluidly connecting the oxidant generator to the reaction chamber via the oxidant container to supply the second oxidant to the reaction chamber using the first oxidant as a transfer gas.

5. The apparatus of claim 4 wherein the oxidant provider is further operable to supply the first oxidant to the reaction chamber without the second oxidant.

6. The apparatus of claim 4 including:
a) a first process valve installed in the first supply line to selectively interrupt and permit flow of the first oxidant toward the reaction chamber; and
b) a first selection valve that operates inversely to the first process valve, to selectively interrupt and permit the flow of the first oxidant toward the oxidant container from the oxidant generator.

7. The apparatus of claim 4 including a second process valve that operates inversely to the first process valve to selectively interrupt and permit flow of the second oxidant toward the reaction chamber from the oxidant container.

8. The apparatus of claim 4 wherein the oxidant generator is operable to generate ozone.

9. The apparatus of claim 4 including H₂O stored in the oxidant container.

10. The apparatus of claim 4 wherein the oxidant container includes:
a) a canister, wherein the second oxidant is disposed in the canister up to a predetermined level;
b) a pressurization line positioned over the second oxidant in the canister to provide the first oxidant to the canister; and
c) a gas supply line positioned over the second oxidant in the canister to exhaust the mixture gas of the first and second oxidants from the canister;
d) wherein the pressurization line is connected to the oxidant generator and the gas supply line is connected to the reaction chamber.

11. An apparatus for depositing a thin film comprising:
a) a reaction chamber;
b) an oxidant generator to generate a first oxidant;
c) an oxidant container;
d) a second oxidant stored in the oxidant container;
e) a reaction material container;
f) a reaction gas stored in the reaction material container;
g) an inert gas generator to generate an inert gas;
h) a drainage pump to exhaust gas from the apparatus;
i) a first supply line to supply the first oxidant directly to the reaction chamber from the oxidant generator;
j) a second supply line connecting the oxidant generator to the reaction chamber via the oxidant container to provide the second oxidant to the reaction chamber using the first oxidant as a transfer gas;
k) a third supply line to supply the inert gas directly to the reaction chamber from the inert gas generator;
l) a fourth supply line connecting the inert gas generator to the reaction chamber via the reaction material container to supply the reaction gas to the reaction chamber using the inert gas as a transfer gas; and
m) a drainage line diverging from the fourth supply line to exhaust the inert gas directly to the drainage pump.

12. The apparatus of claim 11 including a liquid source of the second oxidant stored in the oxidant container.

13. The apparatus of claim 11 including:
a) a first process valve installed in the first supply line to selectively interrupt and permit flow of the first oxidant toward the reaction chamber;
b) a first selection valve that operates inversely to the first process valve to selectively interrupt and permit flow of the first oxidant toward the oxidant container from the oxidant generator; and
c) a second process valve that operates inversely to the first process valve to selectively interrupt and permit flow of the second oxidant toward the reaction chamber from the oxidant container.

14. The apparatus of claim 11 including:
a) a third process valve installed in the third supply line to selectively interrupt and permit flow of the inert gas toward the reaction chamber;
b) a second selection valve installed in the fourth supply line upstream from the reaction material container to selectively interrupt and permit flow of the inert gas toward the reaction material container; and
c) a drainage valve installed in the drainage line and that operates inversely to the second selection valve to selectively interrupt and permit flow of the inert gas toward the drainage pump.

15. The apparatus of claim 11 including:
a) a first supply valve to selectively interrupt and permit flow of the first and second oxidants toward the reaction chamber;
b) a second supply valve to selectively interrupt and permit flow of the inert gas toward the reaction chamber; and
c) a third supply valve to selectively interrupt and permit flow of the reaction gas that flows toward the reaction chamber.

16. The apparatus of claim 15 including:
a) a first bypass valve that operates inversely to the first supply valve to exhaust the first and second oxidants to the drainage pump;
b) a second bypass valve that operates inversely to the second supply valve to exhaust the inert gas to the drainage pump; and
c) a third bypass valve to exhaust the reaction gas to the drainage pump.

17. The apparatus of claim 11 wherein the oxidant generator is operable to generate ozone.

18. The apparatus of claim 11 including H₂O stored in the oxidant container.

19. The apparatus of claim 11 wherein the oxidant container comprises:
a) a canister, wherein the second oxidant is stored in the canister up to a predetermined level;
b) a pressurization line positioned over the second oxidant in the canister to provide the first oxidant to the canister; and
c) a gas supply line positioned over the second oxidant in the canister to exhaust the second oxidant from the canister;
d) wherein the pressurization line is connected to the second supply line upstream from the oxidant container, and the gas supply line is connected to the second supply line downstream of the oxidant container.

20. An apparatus for depositing a thin film, the apparatus comprising:
a) a reaction chamber;
b) an oxidant generator to generate a first oxidant;
c) an oxidant container to generate a second oxidant;
d) a second oxidant stored in the oxidant container;
e) a reaction material container;
f) a reaction gas stored in the reaction material container;
g) an inert gas generator to generate an inert gas;
h) a drainage pump to exhaust gas from the apparatus;
i) a first supply line to supply the first oxidant directly to the reaction chamber from the oxidant generator;
j) a second supply line connecting the oxidant generator to the reaction chamber via the oxidant container to provide the second oxidant to the reaction chamber using the first oxidant as a transfer gas;
k) a third supply line to supply the inert gas directly to the reaction chamber from the inert gas generator; and
l) a fourth supply line diverging from the third supply line and connecting the inert gas generator to the reaction chamber via the reaction material container to supply the reaction gas to the reaction chamber using the inert gas as a transfer gas.

21. The apparatus of claim 20 including a liquid source of the second oxidant stored in the oxidant container.

22. The apparatus of claim 20 including:
a) a first process valve installed in the first supply line to selectively interrupt and permit flow of the first oxidant toward the reaction chamber;
b) a first selection valve to selectively interrupt or permit flow of the first oxidant toward the first oxidant container from the oxidant generator; and
c) a second process valve that operates inversely to the first process valve to selectively interrupt and permit flow of the second oxidant to the reaction chamber from the oxidant container.

23. The apparatus of claim 20 including:
a) a third process valve installed in the third process line to selectively interrupt and permit flow of the inert gas toward the reaction chamber;
b) a second selection valve that operates inversely to the third process valve to selectively interrupt and permit flow of the inert gas toward the reaction material container from the inert gas generator; and
c) a fourth process valve that operates inversely to the third process valve to selectively interrupt and permit flow of the reaction gas toward the reaction chamber from the reaction container.

24. The apparatus of claim 20 including:
a) a first supply valve to selectively interrupt and permit flow of the first and second oxidants toward the reaction chamber; and
b) a second supply valve to selectively interrupt and permit flow of the inert gas and the reaction gas toward the reaction chamber.

25. The apparatus of claim 24 including:
a) a first bypass valve that operates inversely to the first supply valve to selectively exhaust the first and second oxidants toward the drainage pump; and
b) a second bypass valve that operates inversely to the second supply valve to exhaust the inert gas and the reaction gas toward the drainage pump.

26. The apparatus of claim 20 wherein the oxidant generator is operable to generate ozone.

27. The apparatus of claim 20 including H₂O stored in the oxidant container.

28. The apparatus of claim 20 wherein the oxidant container includes:
a) a canister, wherein the second oxidant is stored in the canister up to a predetermined level;
b) a pressurization line positioned over the second oxidant in the canister to provide the first oxidant to the canister; and
c) a gas supply line positioned over the second oxidant in the canister to eject a mixture of the first and second oxidants from the canister;
d) wherein the pressurization line is connected to the second supply line upstream from the oxidant container, and the gas supply line is connected to the second supply line downstream from the oxidant container.

29. A method for depositing a thin film, the method comprising:
(a) supplying a reaction gas to a reaction chamber; and
(b) supplying a mixture of a first oxidant and a second oxidant to the reaction chamber, wherein the first oxidant is used as a transfer gas for the second oxidant gas.

30. The method of claim 30 further including supplying the first oxidant to the reaction chamber without the second oxidant.

31. The method of claim 30 including providing a liquid source of the second oxidant.

32. The method of claim 31 including:
(a) providing a vapor phase of the second oxidant above the liquid source; and
(b) mixing the first oxidant with the vapor phase of the second oxidant.

33. The method of claim 30 wherein the first oxidant is ozone and the second oxidant is water vapor.
